(19) United States
(12) Patent Application Publication
(10) Pub. No.: US 2012/0009510 A1
(43) Pub. Date: Jan. 12, 2012

(54) LITHOGRAPHY MASK AND METHOD OF MANUFACTURING SEMICONDUCTOR DEVICE

(75) Inventor: Kenji KAWANO, Yokkaichi (JP)

(73) Assignee: KABUSHIKI KAISHA TOSHIBA, Tokyo (JP)

(21) Appl. No.: 13/177,890

(22) Filed: Jul. 7, 2011

(30) Foreign Application Priority Data
Jul. 12, 2010 (JP) 2010-157789

(51) Int. Cl. G03F 1/00; H01L 21/027

(52) U.S. Cl. 430/5; 430/319

(57) ABSTRACT

A lithography mask is disclosed. The lithography mask is for use with an exposure apparatus which forms an unpatterned first region and a patterned second region that includes groups of desired patterns in a photosensitive layer. The lithography mask includes a transparent substrate; and a patterned light blocking layer that is formed above the transparent substrate and that is configured to block or partially transmit incident light. The patterned light blocking layer includes a first mask pattern that exposes the first region. The first mask pattern includes a periodic pattern having a sub-resolution pitch that is given by an exposure condition of the exposure apparatus.

### CROSS-REFERENCE TO RELATED APPLICATION(S)

This application is based upon and claims the benefit of priority from Japanese Patent Application No. 2010-157789, filed on, Jul. 12, 2010 the entire contents of which are incorporated herein by reference.

### FIELD

Exemplary embodiments disclosed herein generally relate to a lithography mask and a method of manufacturing a semiconductor device.

### BACKGROUND

Advances in microfabrication of semiconductor elements require higher resolution levels in the lithography process. Such requirement has been typically counteracted by exposure apparatuses employing projection optics with higher NA (Numerical Apertures) and shorter wavelength illumination sources. As the design rule becomes ever tighter, different approaches of resolution enhancement techniques have been taken to form sub-lithographic features. Sidewall transfer process is one of such approaches and allows formation of features that further reduces the pitch of features formed by lithography by half.

Though sidewall transfer process is indeed an effective methodology in forming small features, it only permits use of spacer patterns in transferring patterns to the underlying structures and thus, may require additional processes such as deposition, lithography, and etching in order to form features of various shapes.

For instance, in a memory device fabrication, sidewall transfer process may suffice to form a memory cell region configured primarily by dense gratings. However, a peripheral circuit region for controlling write and read operations, etc. directed to the memory cell region, for instance, includes multiple variations of patterns and thus, is likely to require additional or different series of dedicated processes. Responsively, though formed on the same layer level, memory cell region which can be formed efficiently by sidewall transfer process and the peripheral circuit region which requires additional processes may be formed by additional lithography processes.

One possible approach for such additional lithography processes may be performing a first lithography process for patterning the memory cell region with sidewall transfer process and performing a second lithography process for patterning the resist film located above the peripheral circuit region while leaving the resist film located above the memory cell region unpatterned. The photomask used in the second lithography process may have a sizable pattern-free region, assuming that a positive resist film is used, overlying the memory cell region and a patterned region overlying the peripheral circuit region.

In the second lithography process employing the above configured photomask, light transmitted through the sizable pattern-free region produced flare which degrades the optical properties of the patterns of the nearby peripheral circuit region. Such degradation in optical properties was typically observed as dimension variation. For instance, at the wafer level, exposure shots located at the wafer edge which is relatively less sensitive to flare as compared to the wafer center printed resist patterns of larger dimension compared to the exposure shots located at the wafer center. Another example of degradation in optical properties can be observed through reduced optical image contrast. Reduced optical image contrast originating from the memory cell region caused reduction in the process window of the peripheral circuit region.

### BRIEF DESCRIPTION OF THE DRAWINGS

FIG. 1 is a schematic plan view of a resist film patterned using a photomask according to a first exemplary embodiment of the present disclosure;

FIG. 2 is a schematic vertical cross sectional view of the photomask aligned with the resist film taken along the plane indicated by line 2-2 of FIG. 1;

FIG. 3 is a schematic illustration of a lithography system employed in the first exemplary embodiment;

FIG. 4 is a flowchart indicating an exemplary process flow of a method of manufacturing a semiconductor device using the photomask according to the first exemplary embodiment;

FIGS. 5A, 5B, 6A, 6B, 7A, and 7B each indicate one phase of the manufacturing process flow; and

FIG. 8 is a chart indicating the relation between remaining resist thickness and exposure dose.

### DETAILED DESCRIPTION

In one exemplary embodiment, a lithography mask is disclosed. The lithography mask is for use with an exposure apparatus which forms an unpatterned first region and a patterned second region that includes groups of desired patterns in a photosensitive layer. The lithography mask includes a transparent substrate; and a patterned light blocking layer that is formed above the transparent substrate and that is configured to block or partially transmit incident light. The patterned light blocking layer includes a first mask pattern that exposes the first region. The first mask pattern includes a periodic pattern having a sub-resolution pitch that is given by an exposure condition of the exposure apparatus.

In one exemplary embodiment, a method of manufacturing a semiconductor device is disclosed. The method includes coating an underlying structure with a photosensitive layer; and aligning a lithography mask with the underlying structure. The lithography mask includes a transparent substrate and a patterned light blocking layer that is formed above the transparent substrate and that is configured to block or partially transmit incident light. The patterned light blocking layer includes first and second mask patterns that expose first and second regions of the photosensitive layer respectively. The first mask pattern includes a periodic pattern having a sub-resolution pitch given by an exposure condition of an exposure apparatus being employed. The method further includes exposing the photosensitive layer to transfer the second mask pattern of the lithography mask into the second region of the photosensitive layer; and developing by selectively removing the photosensitive layer to pattern the photosensitive layer. The first region has no patterns defined therein and the second region has a pattern corresponding to the second mask pattern of the lithography mask defined therein.

Exemplary embodiments are described hereinafter with references to the accompanying drawings to provide illustrations of the features of the exemplary embodiments. Elements that are identical or similar are represented by identical or similar reference symbols across the figures and are not redescribed. The drawings are not drawn to scale and thus, do not reflect the actual measurements of the features such as the correlation of thickness to planar dimensions and the relative thickness of different layers.

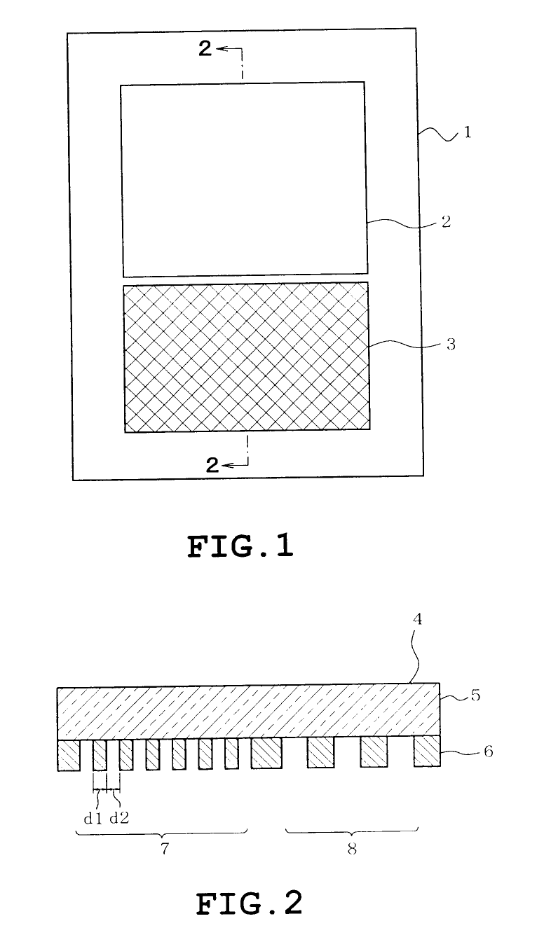

A first exemplary embodiment is described hereinafter with reference to FIGS. 1 to 8.

FIG. 1 is a partial plan view schematically illustrating a photosensitive layer hereinafter referred to as resist (photoresist) film 1. Resist film 1 being coated above a workpiece such as a semiconductor substrate (wafer) is partially patterned as shown using a later described photomask 4. In the first exemplary embodiment, resist film 1 is a positive tone type in which the portion exposed to light is selectively dissolved away into the development liquid in the development process whereas the unexposed portion remains intact.

Still referring to FIG. 1, resist film 1 has unpatterned region 2 also referred to as a first region and patterned region 3 also referred to as a second region located adjacent to unpatterned region 2. Both unpatterned region 2 and patterned region 3 are configured as rectangular regions in the first exemplary embodiment. Unpatterned region 2 is configured as an opening located above, for instance, a memory cell region, where no pattern exists, meaning that resist material was fully removed from this area as the result of exposure and development. Patterned region 3, on the other hand, is located above, for instance, a peripheral circuit region, and is patterned into a variety of desired topographies. The various patterns formed in patterned region 3 are thereafter transferred to underlying structure 11 through etching, lithography, deposition, etc. to form device element features of, for instance, peripheral circuitry. The adjacent unpatterned region 2, residing in the same layer level, may be patterned by another dedicated lithography process and/or a sidewall transfer process to form device element features of, for instance, a memory cell region.

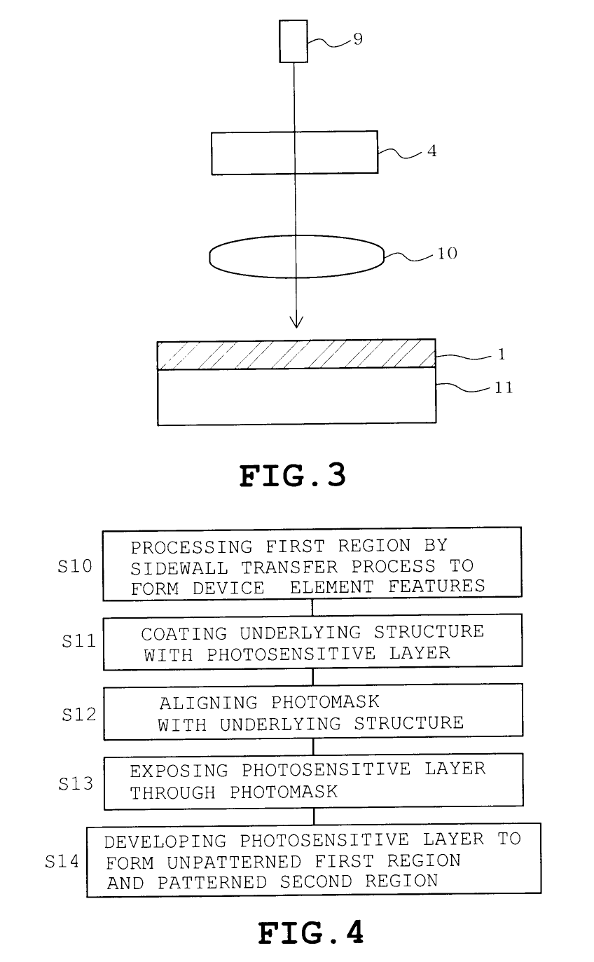

FIG. 2 is a cross sectional view of photomask (reticle) 4, or more generally a lithography mask taken along the plane corresponding to line 2-2 of FIG. 1. Photomask 4 is employed in a lithography system schematically shown in FIG. 3. In the first exemplary embodiment, the lithography system is configured as a projection lithography system typically implemented as an exposure apparatus including light source 9, projection optics 10 and a wafer stage not shown. The exposure apparatus exposes resist film 1 through photomask 4 to pattern resist film 1 as illustrated in FIG. 1 which is further transferred to underlying structure 11.

Light source 9 or more generally EMR (Electromagnetic Radiation) source employed in the first exemplary embodiment is an ArF excimer laser, for instance, with a wavelength of 193 nm. Projection optics 10 employed in the first exemplary embodiment is configured as reduction projection optics with the demagnification ratio set to ¼. Different light sources and/or different magnification ratio may be employed as required.

Still referring to FIG. 2, photomask 4 is configured by transparent substrate 5 typically made of quartz glass and light blocking film 6. Light blocking film 6, typically made of a semi-transparent film is controlled to a transmittance of, for instance, 6%. Light blocking film 6 includes first patterning region 7 which may also be referred to as a first mask pattern and second patterning region 8 which may also be referred to as a second mask pattern located adjacent to first patterning region 7. First patterning region 7 corresponds to the sizable unpatterned region 2 of resist film 1, whereas second patterning region 8 corresponds to patterned region 3 of resist film 1. In the first exemplary embodiment, both first patterning region 7 and second patterning region 8 are configured as rectangular regions and are used to expose the corresponding regions of resist film 1.

First patterning region 7 is entirely patterned with a line-and-space (L/S) pattern of, for instance, 280 nm pitch. The L/S pattern is configured to have periodic width dimension where the width d1 of the lines and width d2 of the spaces maintain, for instance, a 1:1 relation throughout first patterning region 7. Second patterning region 8 contains various patterns including a line-space-pattern having a 600 nm pitch.

The pitch of the L/S pattern in first patterning region is determined through fine tuning with exposure system parameters such that the following relation stands:

P/M≦(λ/(1+σ))NA

where λ represents the wavelength of the light source, NA represents the numerical aperture of the projection optics at the wafer side; σ represents the coherence factor of the light source, M represents the magnification ratio, i.e. demagnification ratio, and P represents the pitch of the line-and-space pattern.

The exposure apparatus employed in the first exemplary embodiment is configured to have NA=0.85, and coherence factor of light source σ=0.9.

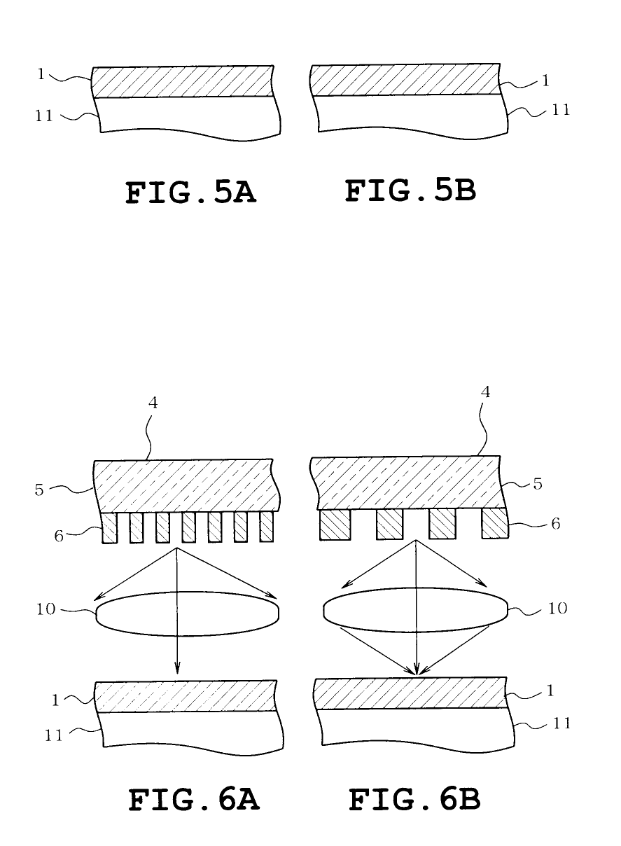

Referring to FIGS. 4 to 7B, a description will be given on an exemplary method of manufacturing a semiconductor device using photomask 4 under the above described configuration and conditions. The method according to the first exemplary embodiment is described through but not limited to manufacturing of a semiconductor memory device typically including a memory cell region and a peripheral circuit region. FIGS. 5A, 6A, and 7A illustrate the processing of the memory cell region corresponding to unpatterned region 2 of resist film 1 and first patterning region 7 of photomask 4. FIGS. 5B, 6B, and 7B illustrate the processing of the peripheral circuit region corresponding to patterned region 3 of resist film 1 and second patterning region 8 of photomask 4.

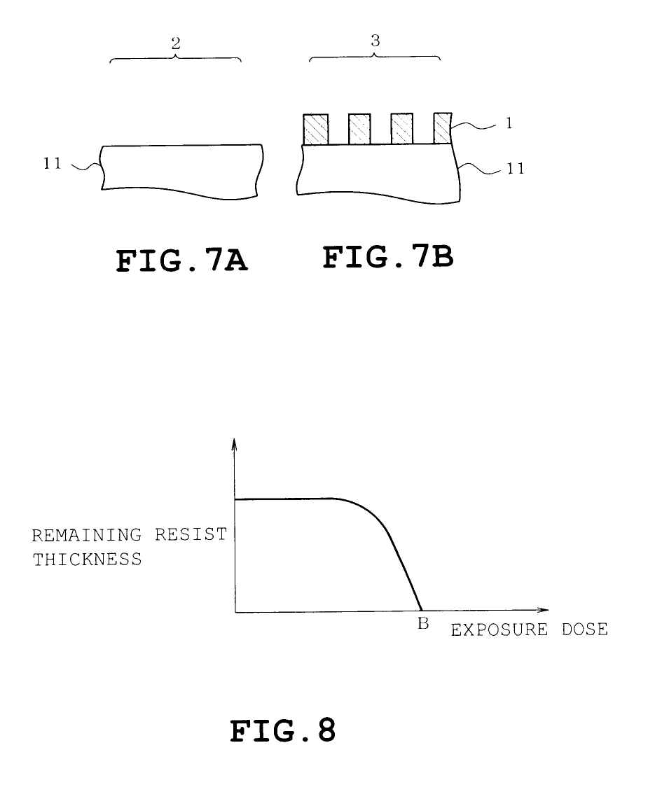

FIG. 4 is a flowchart briefly indicating the manufacturing process flow. The process flow begins with S10 in which unpatterned region 2 is typically subjected to sidewall transfer process to form device element features required for the memory cell region, followed by S11 which coats resist film 1 above underlying structure 11 including the device element features in the unpatterned region 2 as shown in FIGS. 5A and 5B. Then, at S12, photomask 4 containing the above described mask patterns is aligned with underlying structure 11 which is followed by S13 which exposes resist film 1 through photomask 4 by the exposure apparatus as shown in FIGS. 6A and 6B. S13 is followed by S14 which develops the exposed resist film 1 by selectively removing the exposed portions of resist film 1 to form unpatterned region 2 (first region) and patterned region 3 (second region) including device element features required for the peripheral circuit region as shown in FIGS. 7A and 7B. Then, the resist pattern in patterned region 3 is transferred to underlying structure 11, whereas the underlying structure 11 in unpatterned region 2 is processed using the device element features, formed through sidewall transfer process in advance, as a mask to form device element features of the memory cell region and the peripheral circuit region. According to the first exemplary embodiment, the device element features of the memory cell region in the underlying structure 11 can be formed on the same layer level as the device element features of the peripheral circuit region.

In operation, when the wafer is exposed by the exposure apparatus using photomask 4, the L/S pattern pitch in first patterning region 7 of photomask 4 is demagnified or reduced to ¼ through the projection optics 10 from 280 nm to 70 nm. The 70 nm pitch is below the resolution limit of the exposure apparatus employing ArF excimer laser light source having a 193 nm wavelength A. Thus, only the zero diffraction order, propagating in a straight beam, reaches the wafer as shown in FIG. 6A while the first order and greater diffraction orders are scattered off the pupil of the projection optics 10 of the exposure apparatus. Because the first and greater diffraction orders that contribute in image formation do not reach the wafer, no latent image is formed throughout unpatterned region 2 of resist film 1 since only zero diffraction orders strike unpatterned region 2.

The intensity of zero order diffraction beam that reaches the wafer can be controlled by modifying the percentage light blocking film 6 occupies within first patterning region 7 of photomask 4. Stated differently, first patterning region 7 is functionally similar to a filter capable of controlling the transmittance of light after it has passed through photomask 4.

In the first exemplary embodiment, because the L/S pattern formed in first patterning region 7 of photomask 4 has a width dimension where the width d1 of the lines and width d2 of the spaces have a 1:1 relation and the light transmittance of light blocking film 6 is 6%, approximately ½ the intensity of light incident on photomask 4 reaches the wafer. Thus, the presence of first patterning region 7 effectively reduces the exposure dose of the exposure field compared to a photomask lacking such control feature.

On the other hand, the patterns in second pattering region 8 including a L/S pattern of 600 nm pitch is demagnified to ¼ pitch on the wafer to print a line-and-space pattern of 150 nm pitch.

A flare, which is known to occur in the exposure apparatus, is a spreading of incident light into unwanted areas. Flare typically occurs in the presence of a sizable clear/isolated field, or an opening allowing high or full transmission of incident light, situated in the proximity of another relatively darker/dense field, in which incident light is selectively transmitted. Flare is known to adversely affect the optical image properties of resist patterns. For instance, a notable effect of scattered light produced by flare is dimension variation. A L/S resist pattern affected by flare may have a much narrower line/space width than the nominal dimension and the degree of error may vary between different lines/spaces. Flare is also known to degrade process window through degradation in exposure dose latitude and DOF (depth of focus).

The aforementioned disadvantages can be reduced in magnitude by reducing flare. Effective flare is known to decrease with decrease in exposure dose in the clear/isolated field.

According to photomask 4 of the first exemplary embodiment, the light blocking film 6 situated in first patterning region 7 is patterned into a dummy L/S pattern having a 280 nm pitch which is ultimately demagnified into a 70 nm pitch through the projection optics 10 of the exposure apparatus. Because the demagnified pattern has a sub-resolution pitch below the resolution limit of the exposure apparatus, only the zero diffraction order strikes the underlying resist film 1. Moreover, because the dummy L/S pattern was configured to have equal line and space widths, the exposure dose of resist film 1 was effectively reduced to ½ the exposure dose of the conventional exposure apparatus. As reduction in the exposure dose results in a correlated reduction in flare amount as mentioned earlier, the negative impact of flare was also halved. Advantageously, the variation in the L/S pattern dimension above the wafer surface was relaxed by flare reduction as verified in the following.

The demagnified 150 nm-pitch L/S pattern in patterned region 3 formed using a conventional photomask measured a dimension variation range of approximately 19 nm which was obtained by subtracting the minimum dimension from the maximum dimension. In contrast, the use of photomask 4 according to the first exemplary embodiment resulted in a reduced variation range of approximately 9 nm. Moreover, photomask 4 providing the foregoing advantages was fabricated using light blocking film 6, for both first and second pattering regions 7 and 8, which was thereafter patterned into L/S patterns of required pitches for first and second patterning regions 7 and 8. Thus, photomask 4 provided with a dose control feature was obtained without introducing additional process steps to the mask manufacturing process flow.

As described earlier, photomask 4 according to the first exemplary embodiment contains a periodic or repeated dummy L/S pattern of a 280 nm pitch entirely across first patterning region 7 of photomask 4, which corresponds to unpatterned region 2 of resist film 1. The aerial image of the dummy L/S pattern is demagnified to a sub-resolution pitch of 70 nm which does not print as a latent image in resist film 1 above the wafer. Thus, the dummy L/S pattern serves as a sub-resolution feature for controlling the exposure dose. In operation, exposure dose transmitted through first patterning region 7 was reduced through relational control of line width d1 to space width d2, of the dummy L/S pattern thereby reducing effective flare.

The first exemplary embodiment thus, prevents degradation of optical imaging properties of the exposure apparatus to allow high-precision dimension control of the resulting features, which in turn significantly improves product yield. Effective reduction of flare intensity or amount advantageously reduces frequency of maintenance of the exposure apparatus and thus improves its working rate.

The first exemplary embodiment may be modified as follows.

The positive tone type resist film 1 may be replaced by a negative tone type resist film. In such case, the corresponding unpatterned region of such resist film fully remains unpatterned and unremoved after exposure and development.

The sub-resolution L/S pattern configured at 280 nm pitch may be replaced by a L/S pattern of any given pitch as long as the exposure condition of P/M≦(λ/(1+σ))NA is satisfied.

It is further advantageous if pitch P satisfying the above equation is maximized as much as possible to facilitate fabrication of photomask 4.

The widths of the L/S pattern formed in first patterning region 7 of photomask 4 were configured such that line width d1 versus line width d2 was 1:1. Widths d1 and d2 may be configured at different relations depending on target exposure dose. For instance, when the exposure dose and the post-development resist remaining above the wafer show the correlated characteristic indicated in FIG. 8, widths d1 and d2 may be specified at a given ratio that would allow the exposure dose to exceed minimum exposure dose B while minimizing flare as much as possible.

Further, according to the first exemplary embodiment, a L/S pattern was employed as the dummy periodic pattern which was reduced to a pitch below the resolution limit of the exposure apparatus through a reduced projection scheme. Alternatively, a dot pattern may be employed as the dummy periodic pattern, in which case the dot pattern can be configured at the sub-resolution pitch that satisfies the aforementioned exposure condition, that is, P/M≦(λ/(1+σ))NA . In this case also, the exposure dose can be controlled through control of ratio between the area covered by the dots and the area that is not.

Photomask 4 has been configured by transparent substrate 5 and light blocking film 6 comprising a semitransparent film having a transmittance of 6%. Transmittance of the semitransparent film is not limited to 6% but may be controlled as required and may be nontransparent (0%) to serve as a light blocking film that completely blocks transmission of light.

As set forth above, photomask 4 according to the foregoing exemplary and modified embodiments achieve reduction in flare effects by controlling exposure dose through formation of sub-resolution periodic patterns that are not resolved on wafer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A lithography mask for use with an exposure apparatus which forms, in a photosensitive layer, an unpatterned first region and a patterned second region that includes groups of desired patterns, comprising:
a transparent substrate; and
a patterned light blocking layer that is formed above the transparent substrate and that is configured to block or partially transmit incident light, the patterned light blocking layer including a first mask pattern that exposes the first region,
wherein the first mask pattern includes a periodic pattern having a sub-resolution pitch that is given by an exposure condition of the exposure apparatus.

2. The lithography mask according to claim 1, wherein the sub-resolution pitch of the periodic pattern is given by the exposure condition represented by:
P/M≦(λ/(1+σ))NA
where λ represents wavelength of a light source,
NA represents a wafer side numerical aperture,
σ represents a coherence factor of the light source,
M represents a magnification ratio, and
P represents the sub-resolution pitch.

3. The lithography mask according to claim 1, wherein the patterned light blocking layer further includes a second mask pattern that exposes the second region, the second mask pattern including the groups of desired patterns.

4. The lithography mask according to claim 1, wherein the photosensitive layer comprises a positive tone type resist film.

5. The lithography mask according to claim 1, wherein the photosensitive layer comprises a negative tone type resist film.

6. The lithography mask according to claim 1, wherein the periodic pattern comprises a line-and-space pattern.

7. The lithography mask according to claim 1, wherein the periodic pattern comprises a dot pattern.

8. A method of manufacturing a semiconductor device, comprising:
coating an underlying structure with a photosensitive layer;
aligning a lithography mask with the underlying structure, the lithography mask including a transparent substrate and a patterned light blocking layer that is formed above the transparent substrate and that is configured to block or partially transmit incident light, the patterned light blocking layer including first and second mask patterns that expose first and second regions of the photosensitive layer respectively, the first mask pattern including a periodic pattern having a sub-resolution pitch given by an exposure condition of an exposure apparatus being employed;
exposing the photosensitive layer to transfer the second mask pattern of the lithography mask into the second region of the photosensitive layer; and
developing by selectively removing the photosensitive layer to pattern the photosensitive layer, the first region having no patterns defined therein and the second region having a pattern corresponding to the second mask pattern of the lithography mask defined therein.

9. The method according to claim 8, wherein the sub-resolution pitch of the periodic pattern is given by the exposure condition represented by:
P/M≦(λ/(1+σ))NA
where λ represents a wavelength of a light source,
NA represents a wafer side numerical aperture,
σ represents a coherence factor of the light source,
M represents a magnification ratio, and
P represents the sub-resolution pitch.

10. The method according to claim 9, wherein the periodic pattern is a line-and-space pattern.

11. The method according to claim 10, wherein the line-and-space pattern is formed entirely across the first mask pattern and wherein exposing includes controlling exposure dose through control of dimension ratio of line width to space width of the line-and-space pattern.

12. The method according to claim 8, wherein the photosensitive layer comprises a positive tone type resist film.

13. The method according to claim 8, wherein the photosensitive layer comprises a negative tone type resist film.

14. The method according to claim 9, wherein the periodic pattern is a dot pattern.

15. The method according to claim 14, wherein the dot pattern is formed entirely across the first mask pattern and wherein exposing includes controlling exposure dose through control of ratio of dotted area to undotted area of the dot pattern.

16. The method according to claim 8, wherein the periodic pattern comprises a line-and-space pattern.

17. The method according to claim 8, wherein the periodic pattern comprises a dot pattern.

18. The method according to claim 8, wherein the second mask pattern of the lithography mask includes groups of desired patterns.

19. The method according to claim 8, wherein the first region is located within a memory cell region defined in the underlying structure and the second region is located within a peripheral circuit region defined in the underlying structure.

20. The method according to claim 19, further comprising:
forming device element features of the peripheral circuit region by transferring the pattern defined in the second region of the photosensitive layer into the underlying structure; and forming device element features of the memory cell region by a sidewall transfer process in the underlying structure, the device element features of the peripheral circuit region and the memory cell region being formed on the same layer level.
